(19) United States
(12) Patent Application Publication
(10) Pub. No.: US 2024/0104335 A1
(43) Pub. Date: Mar. 28, 2024

(54) MOTION FORECASTING FOR AUTONOMOUS SYSTEMS

(71) Applicant: WAABI Innovation Inc., Toronto (CA)

(72) Inventors: Alexander CUI, Toronto (CA); Sergio CASAS, Toronto (CA); Raquel URTASUN, Toronto (CA)

(73) Assignee: WAABI Innovation Inc., Toronto (CA)

(21) Appl. No.: 18/368,488

(22) Filed: Sep. 14, 2023

Related U.S. Application Data
(60) Provisional application No. 63/407,128, filed on Sep. 15, 2022.

(51) Int. Cl. G06N 3/006; G06F 30/20

(52) U.S. Cl. CPC G06N 3/006; G06F 30/20

(57) ABSTRACT

Motion forecasting for autonomous systems includes obtaining map data of a geographic region and historical trajectories of agents located in the geographic region. The map data includes map elements. The agents and the map elements have a corresponding physical locations in the geographic region. Motion forecasting further includes building, from the historical trajectories and the map data, a heterogeneous graph for the agents and the map elements. The heterogeneous graph defines the corresponding physical locations of the agents and the map elements relative to each other of the agents and the map elements. Motion forecasting further includes modelling, by a graph neural network, agent actions of an agent of the agents using the heterogeneous graph to generate an agent goal location, and operating an autonomous system based on the agent goal location.

### CROSS REFERENCE TO RELATED APPLICATIONS

This application is a non-provisional application of, and thereby claims benefit to, U.S. Patent Application Ser. No. 63/407,128 filed on Sep. 15, 2022. U.S. Patent Application Ser. No. 63/407,128 is incorporated herein by reference in its entirety.

### BACKGROUND

An autonomous system is a self-driving mode of transportation that does not require a human pilot or human driver to move in and react to the real-world environment. Rather, the autonomous system includes a virtual driver that is the decision making portion of the autonomous system. Specifically, the virtual driver controls the actuation of the autonomous system. The virtual driver is an artificial intelligence system that learns how to interact in the real world and then performs the interaction when in the real world.

Part of interacting in the real world is predicting the future motion of agents in the environment. To more safely navigate the real-world environment autonomously, predictions have to be not only accurate and generalize across many scenarios, but also made in a timely manner so that the autonomous system can react appropriately. Namely, existing techniques may compromise accuracy and generalization abilities as compared to computation needs.

Some techniques fully process a scene independently from a viewpoint of each agent, whereby each agent independently builds its own understanding of the environment and then acts with its own understanding accordingly. Such techniques trade accuracy over computation needs, especially in situations with a large number of agents (e.g., crowded urban scenes or highways).

Other techniques process a scene using a same single viewpoint for the predictions of each agent in the scene. For example, such other techniques may use the coordinate frame defined by the autonomous system current pose. In such techniques, the predictions of the agents are not invariant to the single viewpoint from which the scene is encoded, and may need far more training data to generalize to rarely seen or novel autonomous system poses.

### SUMMARY

In general, in one aspect, one or more embodiments relate to a method that includes obtaining map data of a geographic region and historical trajectories of agents located in the geographic region. The map data includes map elements. The agents and the map elements have a corresponding physical locations in the geographic region. The method further includes building, from the historical trajectories and the map data, a heterogeneous graph for the agents and the map elements. The heterogeneous graph defines the corresponding physical locations of the agents and the map elements relative to each other of the agents and the map elements. The method further includes modelling, by a graph neural network, agent actions of an agent of the agents using the heterogeneous graph to generate an agent goal location, and operating an autonomous system based on the agent goal location.

In general, in one aspect, one or more embodiments relate to a system that includes a computer processor and a non-transitory computer readable medium for causing the computer processor to perform operations. The operations include obtaining map data of a geographic region and historical trajectories of agents located in the geographic region. The map data includes map elements. The agents and the map elements have a corresponding physical locations in the geographic region. The operations further include building, from the historical trajectories and the map data, a heterogeneous graph for the agents and the map elements. The heterogeneous graph defines the corresponding physical locations of the agents and the map elements relative to each other of the agents and the map elements. The operations further include modelling, by a graph neural network, agent actions of an agent of the agents using the heterogeneous graph to generate an agent goal location, and operating an autonomous system based on the agent goal location.

In general, in one aspect, one or more embodiments relate to a non-transitory computer readable medium that include computer readable program code for causing a computer system to perform operations. The operations include obtaining map data of a geographic region and historical trajectories of agents located in the geographic region. The map data includes map elements. The agents and the map elements have a corresponding physical locations in the geographic region. The operations further include building, from the historical trajectories and the map data, a heterogeneous graph for the agents and the map elements. The heterogeneous graph defines the corresponding physical locations of the agents and the map elements relative to each other of the agents and the map elements. The operations further include modelling, by a graph neural network, agent actions of an agent of the agents using the heterogeneous graph to generate an agent goal location, and operating an autonomous system based on the agent goal location.

Other aspects of the invention will be apparent from the following description and the appended claims.

### BRIEF DESCRIPTION OF DRAWINGS

FIG. 1 shows an autonomous system with a virtual driver in accordance with one or more embodiments.

FIG. 2 shows a simulation environment for training a virtual driver of an autonomous system in accordance with one or more embodiments of the invention.

FIG. 3 shows a diagram of components of a virtual driver in accordance with one or more embodiments of the invention.

FIG. 4 shows a model diagram of components of a virtual driver in accordance with one or more embodiments of the invention.

FIG. 5 shows a flowchart for motion forecasting for autonomous systems in accordance with one or more embodiments of the invention.

FIG. 6 shows a flowchart for building a heterogeneous graph in accordance with one or more embodiments of the invention.

FIG. 7 shows a flowchart for motion forecasting of an agent using a heterogeneous graph in accordance with one or more embodiments of the invention.

FIG. 8 shows an example diagram of pairwise encoding in accordance with one or more embodiments of the invention.

FIG. 9 shows an example diagram of pairwise relative positional encoding in accordance with one or more embodiments of the invention.

FIG. 10 shows an example diagram of a pair wise relative heterogeneous graph neural network (GNN) in accordance with one or more embodiments of the invention.

FIG. 11 shows an example of a model diagram in accordance with one or more embodiments of the invention.

FIGS. 12A and 12B show a computing system in accordance with one or more embodiments of the invention.

Like elements in the various figures are denoted by like reference numerals for consistency.

### DETAILED DESCRIPTION

In general, embodiments are directed to motion forecasting of agents in a geographic region for autonomous systems. In particular, the geographic region includes the agents (including the autonomous system) and various map elements. The agents are the actors in the geographic regions that are capable of independent decision making and movement. The map elements are physical portions of the geographical region that may be reflected in a map of the geographic region.

One or more embodiments build a shared viewpoint invariant encoding of the geographic region so that the motion forecasting is performed both in real time while maintaining or increasing accuracy. The shared viewpoint invariant encoding is a heterogenous graph that is used to perform the motion forecasting of each of multiple agents. The heterogeneous graph is a single data structure for the agents and the map elements in the geographic region. In the heterogeneous graph, physical locations of the agents and the map elements are defined relative to each other. Namely, for each of the agents, the heterogeneous graph encodes the agent's position in the geographic region as a position relative to other agents in the heterogeneous graph and relative to map elements in the heterogeneous graph. Similarly, for each of the map elements, the heterogeneous graph encodes the map element's position in the geographic region as a position relative to other map elements in the geographic region.

After building the heterogenous graph, the heterogeneous graph is used to model agent actions and decode the agent's goal location of each of multiple agents. The agent's goal location is the predicted future location of the agent at a fixed point in time in the future. Thus, the heterogeneous graph does not have a fixed point coordinate system and does not have a separate scene encoding for each agent. Rather, the heterogeneous graph is used to determine multiple agent goal locations. Based on the agent goal locations, the autonomous system operates. For example, the autonomous system may act to avoid collision with other agents.

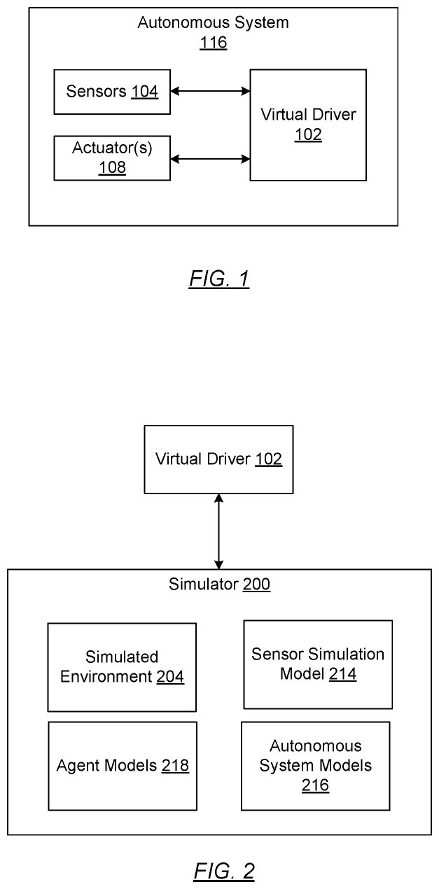

FIGS. 1 and 2 show example diagrams of the autonomous system and virtual driver. Turning to FIG. 1, an autonomous system (116) is a self-driving mode of transportation that does not require a human pilot or human driver to move and react to the real-world environment. The autonomous system (116) may be completely autonomous or semi-autonomous. As a mode of transportation, the autonomous system (116) is contained in a housing configured to move through a real-world environment. Examples of autonomous systems include self-driving vehicles (e.g., self-driving trucks and cars), drones, airplanes, robots, etc.

The autonomous system (116) includes a virtual driver (102) that is the decision making portion of the autonomous system (116). The virtual driver (102) is an artificial intelligence system that learns how to interact in the real world and interacts accordingly. The virtual driver (102) is the software executing on a processor that makes decisions and causes the autonomous system (116) to interact with the real-world including moving, signaling, and stopping or maintaining a current state. Specifically, the virtual driver (102) is decision making software that executes on hardware (not shown). The hardware may include a hardware processor, memory or other storage device, and one or more interfaces. A hardware processor is any hardware processing unit that is configured to process computer readable program code and perform the operations set forth in the computer readable program code.

A real world environment is the portion of the real world through which the autonomous system (116), when trained, is designed to move. Thus, the real world environment may include concrete and land, construction, and other objects in a geographic region along with agents. The agents are the other agents in the real world environment that are capable of moving through the real world environment. Agents may have independent decision making functionality. The independent decision making functionality of the agent may dictate how the agent moves through the environment, and may be based on visual or tactile cues from the real world environment. For example, agents may include other autonomous and non-autonomous transportation systems (e.g., other vehicles, bicyclists, robots), pedestrians, animals, etc.

Stationary and nonstationary inanimate objects (e.g., loose tires parts, balls, debris, and other inanimate objects lacking decision making abilities) may also be represented as agents in the agent layer of the heterogeneous graph. However, such inanimate objects are not proactive to other agents and, as such, may be encoded with properties indicating the lack of decision making ability.

The real world environment changes as the autonomous system (116) moves through the real world environment. For example, the geographic region may change and the agents may move positions, including new agents being added and existing agents leaving.

In the real world, the geographic region is an actual region within the real-world that is surrounding the autonomous system. Namely, from the perspective of the virtual driver, the geographic region is the region through which the autonomous system moves. The geographic region includes actual agents and actual map elements that are located in the real world. Namely, the actual agents and actual map elements each have a physical location in the geographic region that denote an exact spot or place in which the corresponding agent or map element is located. The map elements are stationary in the geographic region, whereas the agents may be stationary or nonstationary in the geographic region. For example, the map elements may be a curb, a particular lane marker, a particular location between two lane markers or a lane marker and a curb, a light, a stop sign, or a construction zone, or other physical object/location in the geographic region. The map elements may or may not be demarcated in the real world. For example, if the map element is a particular spot in the real world that is between two lane markers, the particular spot exists in the real world and has a physical location, but the particular spot may not have any signposts or other markings in the real world that are at the particular spot. In one or more embodiments, a map of the geographic region directly or indirectly specify the stationary locations of the map elements.

In order to interact with the real-world environment, the autonomous system (116) includes various types of sensors (104), such as LiDAR sensors amongst other types, which are used to obtain measurements of the real-world environment, and cameras that capture images from the real world environment. The autonomous system (116) may include other types of sensors as well. The sensors (104) provide input to the virtual driver (102).

In addition to sensors (104), the autonomous system (116) includes one or more actuators (108). An actuator is hardware and/or software that is configured to control one or more physical parts of the autonomous system based on a control signal from the virtual driver (102). In one or more embodiments, the control signal specifies an action for the autonomous system (e.g., turn on blinker, apply breaks by a defined amount, apply accelerator by a defined amount, turn steering wheel or tires by a defined amount, etc.). The actuator(s) (108) are configured to implement the action. In one or more embodiments, the control signal may specify a new state of the autonomous system and the actuator may be configured to implement the new state to cause the autonomous system to be in the new state. For example, the control signal may specify the that the autonomous system should turn by a certain amount while accelerating at a predefined rate, while the actuator determines and causes the wheel movements and the amount of acceleration on the accelerator to achieve the certain amount of turn and acceleration rate.

The testing and training of virtual driver (102) of the autonomous systems in the real-world environment is unsafe because of the accidents that an untrained virtual driver can cause. Thus, as shown in FIG. 2, a simulator (200) is configured to train and test a virtual driver (102) of an autonomous system. For example, the simulator may be a unified, modular, mixed-reality, closed-loop simulator for autonomous systems. The simulator (200) is a configurable simulation framework that enables not only evaluation of different autonomy components of the virtual driver (102) in isolation, but also as a complete system in a closed-loop manner. The simulator reconstructs “digital twins” of real world scenarios automatically, enabling accurate evaluation of the virtual driver at scale. The simulator (200) may also be configured to perform mixed-reality simulation that combines real world data and simulated data to create diverse and realistic evaluation variations to provide insight into the virtual driver's performance. The mixed reality closed-loop simulation allows the simulator (200) to analyze the virtual driver's action on counterfactual “what-if” scenarios that did not occur in the real-world.

The simulator (200) creates the simulated environment (204) that is a virtual world in which the virtual driver (102) is a player in the virtual world. The simulated environment (204) is a simulation of a real-world environment, which may or may not be in actual existence, in which the autonomous system is designed to move. As such, the simulated environment (204) includes a simulation of the objects (i.e., simulated objects or agents) and background in the real world, including the natural objects, construction, buildings and roads, obstacles, as well as other autonomous and non-autonomous objects. The simulated environment simulates the environmental conditions within which the autonomous system may be deployed. The simulated objects may include both stationary and non-stationary objects. Non-stationary objects are agents in the real-world environment.

In the simulated environment, the geographic region is a realistic representation of a real-world region that may or may not be in actual existence. Namely, from the perspective of the virtual driver, the geographic region appears the same as if the geographic region were in existence if the geographic region does not actually exist, or the same as the actual geographic region present in the real world. The geographic region in the simulated environment includes virtual agents and virtual map elements that would be actual agents and actual map elements in the real world. Namely, the virtual agents and virtual map elements each have a physical location in the geographic region that denote an exact spot or place in which the corresponding agent or map element is located. The map elements are stationary in the geographic region, whereas the agents may be stationary or nonstationary in the geographic region. As with the real-world, a map exists of the geographic region that specifies the physical locations of the map elements.

The simulator (200) includes an autonomous system model (216), sensor simulation models (214), and agent models (218). The autonomous system model (216) is a detailed model of the autonomous system in which the virtual driver (102) will execute. The autonomous system model (216) includes model, geometry, physical parameters (e.g., mass distribution, points of significance), engine parameters, sensor locations and type, firing pattern of the sensors, information about the hardware on which the virtual driver executes (e.g., processor power, amount of memory, and other hardware information), and other information about the autonomous system. The various parameters of the autonomous system model may be configurable by the user or another system.

The autonomous system model (216) includes an autonomous system dynamic model. The autonomous system dynamic model is used for dynamics simulation that takes the actuation actions of the virtual driver (e.g., steering angle, desired acceleration) and enacts the actuation actions on the autonomous system in the simulated environment to update the simulated environment and the state of the autonomous system. The interface between the virtual driver (102) and the simulator (200) may match the interface between the virtual driver (102) and the autonomous system in the real world. Thus, to the virtual driver (102), the simulator simulates the experience of the virtual driver within the autonomous system in the real world.

In one or more embodiments, the sensor simulation model (214) models, in the simulated environment, active and passive sensor inputs. The sensor simulation models (114) are configured to simulates the sensor observations of the surrounding scene in the simulated environment (204) at each time step according to the sensor configuration on the vehicle platform. Passive sensor inputs capture the visual appearance of the simulated environment including stationary and nonstationary simulated objects from the perspective of one or more cameras based on the simulated position of the camera(s) within the simulated environment. Example of passive sensor inputs include inertial measurement unit (IMU) and thermal. Active sensor inputs are inputs to the virtual driver of the autonomous system from the active sensors, such as LiDAR, RADAR, global positioning system (GPS), ultrasound, etc. Namely, the active sensor inputs include the measurements taken by the sensors, the measurements being simulated based on the simulated environment based on the simulated position of the sensor(s) within the simulated environment.

Agent models (218) represents an agent in a scenario. An agent is a sentient being that has an independent decision making process. Namely, in a real world, the agent may be animate being (e.g., person or animal) that makes a decision based on an environment. The agent makes active movement rather than or in addition to passive movement. An agent model, or an instance of an actor model may exist for each agent in a scenario. The agent model is a model of the agent. If the agent is in a mode of transportation, then the agent model includes the model of transportation in which the agent is located. For example, actor models may represent pedestrians, children, vehicles being driven by drivers, pets, bicycles, and other types of actors.

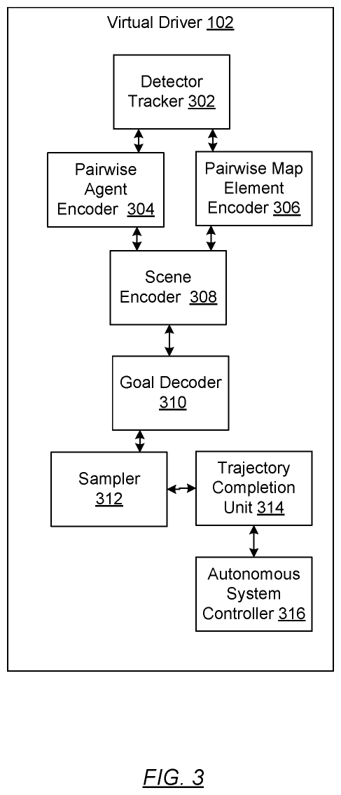

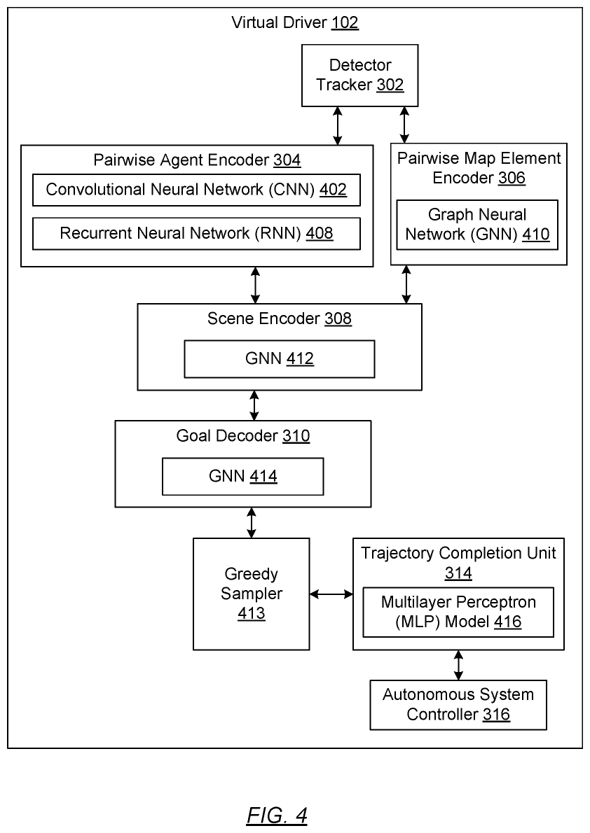

FIG. 3 shows a schematic diagram of the virtual driver (102) in accordance with one or more embodiments. Specifically, FIG. 3 shows a schematic diagram of a motion forecasting system that may be in the virtual driver. As shown in FIG. 3, the virtual driver (102) includes a detector tracker (302), a pairwise agent encoder (304), a pairwise map element encoder (306), a scene encoder (308), a goal decoder (310), a sampler (312), a trajectory completion unit (314), and an autonomous system controller (316). Each of these components is described below.

The detector tracker (302) is a software process configured to obtain sensor data from the sensor inputs and generate a fixed point view of the geographic region. In one or more embodiments, the detector tracker (302) is configured to generate a birds eye view of the geographic region based on camera and LiDAR data. For example, the LiDAR data may include information about the distance to objects (e.g., map elements, agents, other objects), while the camera data captures the object images. The detector tracker (302) may have a convolutional neural network to identify the objects from the camera images. The detector tracker may combine the identification of the objects with the LiDAR data to identify the distance to the object and data from a map to determine absolute position of the object with respect to the Earth. The detector tracker (302) may be configured to overlay the object locations with the map to generate a birds eye view of the geographic region with the objects in the geographic region and a first set of features of the objects.

For each agent, the detector tracker (302) is a software process configured to combine the agent identification with the LiDAR data to track the agent over time and generate a historical trajectory of the agent. A historical trajectory of the agent is a time series list of the position(s) of the agent over time. The historical trajectory is historical in that the positions are positions in which the agent was or currently is rather than a forecasted future position of the agent. For example, the historical trajectory of an agent associates, for multiple time steps in a series of time, a past or current position with the time in which the agent is at the position. The time may be relatively defined to a predefined point in time (e.g., 24 hour clock timestamp, timestamp from the starting of the autonomous vehicle, etc.). The position may be a position relative to a fixed point, such as the position relative to the birds eye view (e.g., top down view) of the geographic region. Thus, the output of the detector tracker (302) includes a set of historical trajectories of agents, each associated with an agent identifier. The output of the detector tracker (302) may also include an additional feature set of the agent.

Continuing with FIG. 3, a pairwise agent encoder (304) and a pairwise map element encoder (306) are connected to the historical tracker. The pairwise agent encoder (304) is a software process configured to calculate, for each agent, the relative position of the agent with respect to other agents in the geographic region. The pairwise agent encoder (304) may further be configured to calculate, for each agent, the relative current position of the agent with respect to past positions of the agent. Rather than a fixed point encoding that spans multiple agents, the relative position encoding is a set of relative positions for an agent that specify the position of the agent in terms that are relative to other agents, including the autonomous system. In one or more embodiments, the relative position is defined by the distance between the two agents (e.g., the agent and another agent or the agent and itself in a previous time) and the angle between the headings of the agents. The pairwise agent encoder (304) may be further configured to encode, in agent position encodings, the relative positions of the agent into a feature set for the agent in one or more embodiments.

The output of the pairwise agent encoder (304) may be agent position encodings in an agent layer of a heterogeneous graph. The agent layer is a graph data structure having agent nodes connected by edges. An agent node is for an individual corresponding agent. The agent node may have an attribute of a feature set defining general features of the agent. The edge connecting two agent nodes may be an agent position encoding that is generated by encoding of the relative positions of the corresponding two agents represented by the agent nodes. The agent position encoding encodes the relative position of the agent. The relative current position of the agent with respect to past positions of the agent may be based encoded in the agent node or in an edge connecting an agent node to itself.

The pairwise map element encoder (306) is a software process configured to encode map elements of a geographic region as relative positions with respect to each other. Specifically, the pairwise map element encoder (306) is configured to calculate, for each map element, the relative position of the map element with respect to other map elements in the geographic region. Thus, for each map element, a set of relative positions of the map element with respect to other map elements may be defined. The pairwise map element encoder (306) may be further configured to encode the relative positions into a feature set for a pair of map elements. Additionally, a map element may have a feature set defining the map element. For example, the feature set may encode size information, the type of geographic region in which the map element is located (e.g., urban, rural, etc.), type of map element, and other features about the map element or the properties surrounding the map element.

The output of the map element encoder (306) may be map element encodings in a map layer of the heterogeneous graph. The map layer is a graph data structure having a map element nodes connected by edges. The map element node is for an individual corresponding map element. The edges connecting two map element nodes may be associated with a relative position encoding of the corresponding pair of map element nodes. The map element node may be associated with a feature set that is generated based on general features of the map element.

The scene encoder (308) is a software process configured to generate a heterogeneous graph data structure from the output of the pairwise map element encoder (306) and the pairwise agent encoder (304). In one or more embodiments, the scene encoder (308) is configured to add to the agent layer and the map element layer a set of edges connecting agent nodes to map element nodes to generate the heterogeneous graph. The scene encoder (308) is further configured to update the heterogeneous graph to encode the overall scene. For example, the updating of the heterogeneous graph may be to pass messages between the nodes (e.g., map element nodes and agent nodes) and edges to encode the overall scene (e.g., the map, agents, and historical trajectories of agents). The features associated with an edge may be updated to reflect that features of other edges.

A goal decoder (310) is a software process configured to model agent actions using the heterogenous graph and generate one or more agent goal locations. An agent action is an action that an agent may perform given the overall scene. In one or more embodiments, the agent actions may not be specified or identified by the goal decoder. Rather, the goal decoder models the agent actions when the goal decoder discerns the agent goal locations for the agent. The agent goal location is a projected location of the agent after a predefined period of time. The agent goal location may or may not be a desired location by the agent. For example, consider the scenario that the autonomous system and another agent are vehicles. In the example, if the driver of the other agent (i.e., driver of the other vehicle) has lost control such as by being in process of having an accident, the agent goal location of the other agent may not be the desired position that the driver intends, but rather a projected position of the other vehicle. Contrarily, if the driver of the other vehicle is making a turn and has full control of the other vehicle, the agent goal location may be the desired position of the driver. In one or more embodiments, the goal decoder (310) is configured to output multiple agent goal locations and corresponding probabilities for each of the multiple agent goal locations.

The sampler (312) is a software process that is configured to sample the agent goal locations based on the corresponding probabilities to select one or more agent goal locations.

The trajectory completion unit (314) is a software process configured to generate a forecasted trajectory to a particular agent goal location. Namely, the agent goal location is a forecasted location of the agent at a particular time. The forecasted trajectory is the path to the forecasted location. The forecasted trajectory may be defined by pairs of time steps and positions, whereby a pair specifies the projected position of the agent at the particular time step, and whereby the time step is a time between the current time and the particular time in which the agent is projected to be at the projected agent goal location.

The autonomous system controller (316) is a software process configured to send a control signal to an actuator of the autonomous system. The autonomous system controller (316) is configured to determine an action for the autonomous system to perform based at least in part on the agent goal locations of the agent. Notably, as in the real world, a single agent may have multiple possible agent goal locations and multiple possible trajectories. The autonomous system controller may be configured to account for the multiple possible agent goal locations when determining the action for the autonomous system.

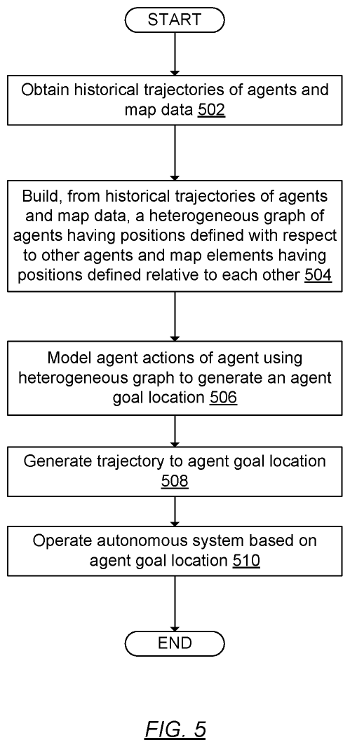

In one or more embodiments, FIG. 3 is implemented as a machine learning framework having a variety of machine learning models. FIG. 4 shows a model diagram of components of a virtual driver in accordance with one or more embodiments of the invention. Same numbered components between FIG. 4 and FIG. 3 have the same functionality described above with reference to FIG. 3. While FIG. 4 shows the model diagram, unless expressly claimed, one or more embodiments may be implemented using other machine learning models or other algorithmic techniques. Further, the models in FIG. 4 may be combined with other software process to implement the particular component.

Turning to FIG. 4, the pairwise agent encoder (304) may include a convolutional neural network (CNN) (402) and a recurrent neural network (RNN) (408). The CNN may be a one dimensional CNN with residual connections. The output of the CNN may be passed to a RNN (408) may be a gated recurrent unit (GRU). The final hidden state of the GRU may be the encoding of a particular agent's trajectory.

The pairwise map element encoder (306) may include a GNN (410). Generally, a graph neural network is a type of artificial neural network that implements message passing on a graph data structure with a nodes and edges. Messages are passed between the nodes and one or more update functions applied to the messages to generate an new set of values. The update functions may exist for the edges of the graph, the nodes of the graph, and any global features of the graph. The process of updating the graph may be iteratively repeated for multiple rounds of message passing. In the pairwise map element encoder (306), the graph data structure is the map layer described above.

The scene encoder (308) may also include a GNN (412). The GNN in the scene encoder (308) may be a different GNN than in the pairwise map element encoder (306). For example, the scene encoder may have different update functions than in the pairwise map element encoder (306). In one or more embodiments, the scene encoder has individual linear layers for each edge type. For example, an edge between two agent nodes uses a different linear layer than an edge between two map element nodes, which are both different linear layers than an edge between an agent node and a map element node.

A goal decoder (310) may also have a GNN that is different from the GNNs (410, 412, 414) of the scene encoder (308) and the pairwise map element encoder (306). For example, a different set of weights on the various layers may be used for the goal decoder.

In one or more embodiments, the sampler (312) in FIG. 3 is a greedy sampler (413). A greedy sampler (413) selects the agent goal location based on the probabilities of each agent goal location.

The trajectory completion unit (314) may be implemented using a multilayer perceptron (MLP) model (416). Generally, an MLP model is a feedforward artificial neural network having at least three layers of nodes. The layers include an input layer, a hidden layer, and an output layer. Each layer has multiple nodes. Each node includes an activation function with learnable parameters. Through training and backpropagation of losses, the parameters are updated and correspondingly, the MLP model improves in making predictions. In the trajectory completion unit (314), the set of predictions are each the positions of a particular agent at a particular time step and may include a probability given the current position of the agent and the agent goal location. Thus, the set of predictions output by the MLP model correspond to the projected trajectory for the agent.

While the components of FIG. 3 and FIG. 4 are shown as part of the virtual driver (102), one or more of the components of FIG. 3 and FIG. 4 may be implemented in the simulator. For example, the simulator may have each of the components of FIG. 3 or FIG. 4 and use the actions to simulate future agent actions in the simulated environment.

While FIGS. 1-4 show a configuration of components, other configurations may be used without departing from the scope of the invention. For example, various components may be combined to create a single component. As another example, the functionality performed by a single component may be performed by two or more components.

FIGS. 5-7 show flowcharts in accordance with one or more embodiments. While the various steps in these flowcharts are presented and described sequentially, at least some of the steps may be executed in different orders, may be combined or omitted, and at least some of the steps may be executed in parallel. Furthermore, the steps may be performed actively or passively.

FIG. 5 shows a flowchart for motion forecasting for autonomous systems in accordance with one or more embodiments of the invention. In Block 502, historical trajectories of agents and map data are obtained. In one or more embodiments, the historical trajectories are obtained from another system. In some embodiments, the historical trajectories may be obtained by the detector tracker generating the historical trajectories from input sensor data. For example, sensor data captured from various sensors on the autonomous system, or simulated by the simulator for the autonomous system, are provided to the detector tracker. The detector tracker combines the current sensor input with past trajectory information to generate the historical trajectories. Thus, a set of historical trajectories are obtained, whereby each historical trajectory corresponds to a particular agent. As the autonomous system and agents moves through the environment, the geographic region may change and agents are added and removed. The set of agents having a historical trajectory are updated based on the movement. Thus, the set of historical trajectories may change for previous iterations of motion forecasting as for the current iteration. In one or more embodiments, the autonomous system is also considered an agent for the purposes of obtaining the historical trajectories and generating the heterogenous graph. Specifically, because agents may react to the autonomous system, the heterogeneous graph also includes the autonomous system. The map data is obtained for the current geographic region around the autonomous system. The virtual driver may have access through a predefined location to the map data.

In Block 504, from historical trajectories of agents and map data, a heterogeneous graph of agents having positions defined with respect to other agents and map elements having positions defined relative to each other is built. Each agent is associated with a corresponding individual agent node. The current location of each agent as specified in the agent's historical trajectory is compared to the current location of each other agent as specified in the other agent's historical trajectory. In one or more embodiments, pairs of agents that are greater a threshold distance to each other are excluded from further analysis. Remaining pairs of agents each have an edge added between the corresponding agent nodes of the pair. The edge is associated with the relative position of the two agents with respect to each other to generate the agent layer of the heterogeneous graph. A similar process may be performed for map elements to generate the map layer of the heterogenous graph. The agent layer and the map layer may be linked as follow by connecting, using an edge, each agent node to each map element node of a corresponding map element that is closest to or within a threshold distance to the corresponding agent. The relative position between the agent and the map element may be calculated and added to the new edge.

In Block 506, agent actions of a particular agent are modeled using the heterogeneous graph to generate an agent goal location. The agent goal location may be for a particular future point in time. For example, the agent goal location may be for five, ten, or thirty seconds from the current time in which the historical trajectories were obtained. With the reactive and real-time requirements of the autonomous system, the operations to obtain the historical trajectories, building the heterogenous graph, and modeling agent actions may not be performed by a human.

Multiple agent goal locations may be defined. Because the heterogeneous graph is used, the modeling accounts for the relative distances of the agent to other agents. Furthermore, because the heterogeneous graph does not use the particular coordinate frame of a particular agent, the same heterogeneous graph may be used for modeling multiple agent actions. Additionally, because the heterogenous graph is independent of the current pose (e.g., heading, location) of the autonomous system, the amount of training data to train the machine learning model is reduced. Namely, the training data does not need to account for the different poses of the autonomous system when modeling agent actions. In one or more embodiments, Block 506 is repeated for each agent in the geographic region. In one or more embodiments, Block 506 is not performed for the autonomous system but is performed for each other agent in the geographic region.

In Block 508, the trajectory to the agent goal location is generated. In one or more embodiments, after generating at least one agent goal location for an agent in Block 506, the projected trajectory to the agent goal location is generated. Generating the projected trajectory may be performed for the autonomous system to model how the autonomous system moves through the geographic region without collision with the agent. The simulator may model the projected trajectory to determine whether collisions occur based on the agent actions.

In Block 510, the autonomous system is operated based on the agent goal location. If the method of FIG. 5 is performed by the virtual driver, the virtual driver may use the trajectories of the agent and the virtual driver's own path to its destination to determine a current trajectory of the autonomous system that satisfies safety criteria (e.g., avoiding collisions, having stopping distance, etc.) and other criteria (e.g., shortest path, reduced number of lane changes, etc.) and is in furtherance of the moving to the destination. The virtual driver may then output a control signal to one or more actuators. In the real-world environment, the control signal is used by an actuator that causes the autonomous system to perform an action, such as move in a particular direction at a particular speed or acceleration, wait, display a turn signal, or perform other action. In the simulated environment, the control signal is intercepted by a simulator that simulates the actuator and the resulting action of the autonomous system. The simulator simulates the autonomous system thereby training the virtual driver. Namely, the output of simulating the autonomous system in the simulated environment may be used to evaluate the actions of the virtual driver.

In some embodiments, the operations of FIG. 5 are performed by the simulator to project agent actions. For example, the simulator may generate a simulated environment that simulates a virtual agent moving in the geographic region according to the agent goal location using the technique of FIG. 5. The simulator then simulates the sensor input (simulated sensor input) to the virtual driver based on the virtual agent moving to the agent goal location in the geographic region. The virtual driver may output a control signal based at least in part on the simulated sensor input. The operations of the virtual driver may be performed using the same technique described above or a different technique. When the virtual driver outputs the control signal, the simulator further simulates the autonomous system moving in the simulated environment responsive to the control signal.

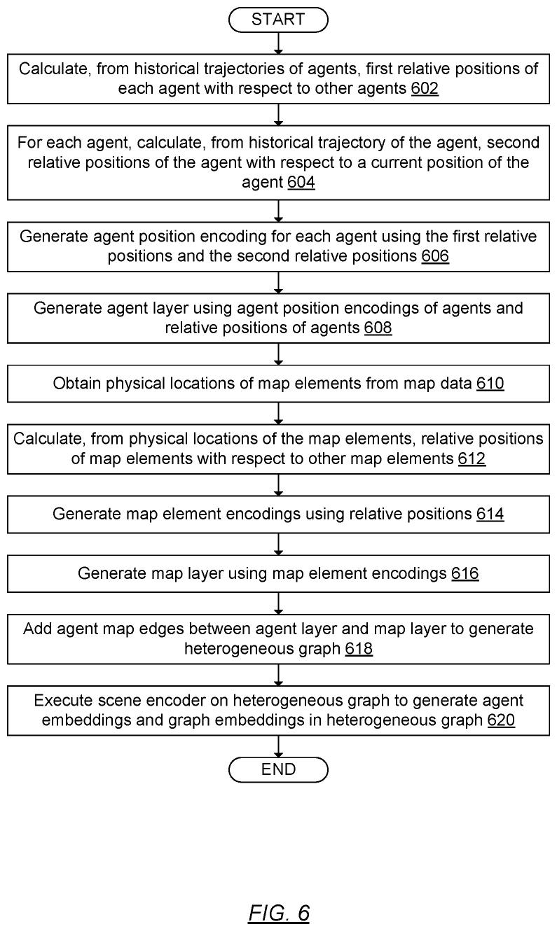

FIG. 6 shows a flowchart for building a heterogeneous graph in accordance with one or more embodiments of the invention. FIG. 6 shows the operations of Block 504 in some embodiments. One or more of the Blocks of FIG. 6 may be used to perform at least a portion of building the heterogeneous graph in Block 504. Blocks 602-608 describe building an agent layer. The processing is performed for each of at least a subset of agents. Each agent is related to an agent node. In one or more embodiments, a one-to-one correspondence may exist between agents and agent nodes.

In Block 602, from the historical trajectories of the agents, the first relative positions of each agent with respect to the other agents is calculated. In one or more embodiments, the process of Block 602 is performed independently and in parallel for multiple agents. From the current location and heading of the agent and the current location and heading of another agent as specified in the corresponding agent trajectories, the relative distance and angle between heading directions is determined. The result is a relative position of the particular agent to another particular agent. If the relative distance is less than a threshold, then an edge is added between the agents. The relative position is associated with the added edge. The process of Block 602 is performed for each pair of agents. The result is, for each agent, a set of edges from the agent node of the agent to the agent node of other agents with the first relative positions.

In Block 604, for each agent, from the historical trajectories of the particular agent, second relative positions of the particular agent with respect to a current position of the particular agent is calculated. From the current location and heading of the particular agent and a previous location and the heading at the previous location of the particular agent, the relative distance and angle between heading directions is determined. For each agent individually, the intermediate result is a relative current position as compared to the previous position of the particular agent. The process may be repeated for each previous position of the particular agent in the trajectory. For each agent individually, the result is a second relative positions of the particular agent that are relative to the previous positions of the particular agent. The second relative positions may be added as an edge of the agent node of the particular agent to itself or added as a property of the agent node of the particular agent.

In Block 606, an agent position encoding for each agent is determined using the first relative positions and the second relative positions of the agent. A single agent position encoding may be generated or multiple agent position encodings may be generated for each agent. For example, for each relative position of the first relative positions, a separate agent position encoding may be generated and added to the edge. For the second relative positions, the second relative positions may be concatenated into a vector ordered by time at which the agent was at the relative positions. The vector may then be encoded. Encoding a position may be performed using a neural network, such as the CNN and RNN described above.

In Block 608, an agent layer is generated using the agent position encodings of the agents and the relative positions of the agents. A GNN may be executed by passing messages between the agent nodes that include the agent position encodings. The result is that agent nodes and edges not only have encodings reflecting the edges and agent nodes directly connected to the agent node or edge, but also edges connecting other agents nodes together.

For example, consider the scenario in which car A, car B, and car C are in the geographic region. Each car is an agent having a corresponding agent node. Car A and car B have a first relative position to each other and car B and car C have a second relative position to each other. Car B will move based on car A and car C, car A will move based on car B and car C, and car C will move based on car A and car B. However, car A may also move based on a projected movement of car B to car C. For example, if the relative position of car B to car C is within a collision distance, then a movement of car B to avoid the collision may affect car A. Namely, if car B is projected to move by car A, the car A may also move based on car A's projection of car B's movement. The agent layer encodes for car A, the relative distances between car B and car C through the message passing and the GNN. By not only having the encodings of the relative distances, but also updating the GNN through multiple iterations of message passing, the agent layer has an encoding that encodes multiple levels of relative positions of the agents with respect to each other.

Continuing with FIG. 6, Blocks 610-616 are directed to generating the map layer. The process of Blocks 610-616 in some embodiments may be performed all or in part prior to performing the agent encoding. For example, if the map does not change, then the map encoding may be performed offline. As another example, certain parts that are immutable, such as map elements between or corresponding to lane markers may be performed offline while other elements are performed in real time.

In Block 610, physical locations of map elements are obtained from the map data. In some embodiments, one or more of the map elements are determined from the map data. For example, if the map data includes lane makers, the map elements may be a defined geographic spot between two lane markers.

In Block 612, from the physical locations of the map elements, the relative positions of the map elements with respect to other map elements are calculated. Calculating the relative positions of the map elements may be performed in a similar manner as discussed above with regards to calculating the relative positions of agents.

In Block 614, map element encodings are generated using the relative positions. The map element encodings encode the features of the map element and encode the relative position.

In Block 616, a map layer is generated using the map element encodings. Each map element corresponds to a map element node in the map layer. The map element nodes are connected by edges based on adjacency between the map element nodes. The edge between two map element nodes are associated with a relative position between the two corresponding map elements to generate the map layer. Further, the graph neural network may be applied to the map layer to further update the map layer.

In Block 618, agent map edges are added by the agent layer and the map layer to generate a heterogeneous graph. In one or more embodiment, an edge is added between an agent node and a map element node when the corresponding agent is within a threshold distance to the corresponding map element as defined by the map and the current position in the historical trajectory of the agent. As another example, an edge may be added between an agent node and map element node when the corresponding map element is adjacent to the corresponding agent. Different techniques may be used to determine which map elements to add to which corresponding agents.

In Block 620, a scene encoder is executed on the heterogeneous graph to generate agent embeddings and graph embeddings in the heterogeneous graph. A GNN may be applied to the heterogeneous graph generated in Block 618. By applying the GNN, each edge and agent node have encodings that reflect not only information about relative positions between adjacent nodes in the heterogeneous graph, but also information about relative positions between other adjacent nodes including the past positions of the agent nodes. Thus, from the perspective of a particular agent, the heterogeneous graph includes information that both directly and indirectly affects the particular agent. By way of an example, a lane closure affecting another agent may affect the particular agent when the other agent moves into the lane of the particular agent. Using the GNN, the edges connected to the agent may include features that are affected by the lane closure. The output of the scene encoder is a set of agent embeddings and a set of graph embeddings. Specifically, each agent node has an agent embedding in the set of agent embeddings and each map element node has a graph embedding in the set of graph embeddings.

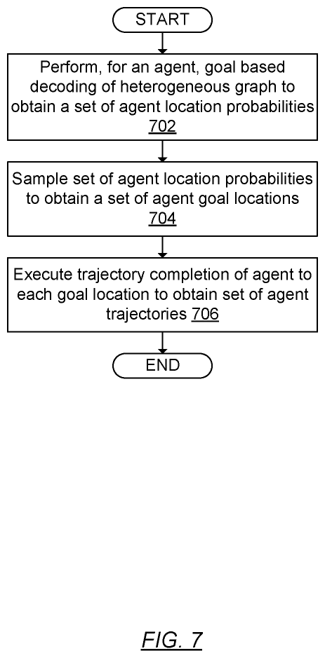

FIG. 7 shows a flowchart for motion forecasting of an agent using a heterogeneous graph in accordance with one or more embodiments of the invention. FIG. 7 may be individually performed for each particular agent in the geographic region. In particular, whereas FIGS. 5 and 6 may be performed for the group of agents in the geographic region, the blocks of FIG. 7 are independently performed for each agent. In some embodiments, FIG. 7 is not performed for the autonomous system. In other embodiments, FIG. 7 is performed for the autonomous system to determine an action for the autonomous system to perform.

In Block 702, goal based decoding of the heterogeneous graph is performed to obtain a set of agent location probabilities. Candidate goals are defined that include the map elements and a continuous set of offsets from the map elements. To account for possible movements of the agent to outside of the geographic region, an additional set of offsets are defined from the current agent position. For the agent, a separate graph data structure is generated from the heterogeneous graph that include the single agent node and the set of map element nodes in the heterogeneous graph. Agent and map node features of the graph data structure of the agent is initialized based on the output of the scene encoder in of Block 620 of FIG. 6. Namely, the agent embedding for the agent and the corresponding graph embedding for each map element is used. A GNN is applied to the graph data structure to generate the agent location probabilities. The agent location probabilities is the probability that the agent will move to the corresponding agent location, defined by map element and offset, at the future time.

In Block 704, the set of agent location probabilities are sampled to obtain a set of agent goal locations. In one or more embodiments, a greedy sampler is used to sample the set of agent location probabilities. The greedy sampler may perform an iterative process to obtain a predefined number of samples. For example, if the greedy sample obtains N samples, the greedy sampler may perform N iterations. In an iteration, the greedy sampler obtains a sample agent location based on the corresponding agent location probability. The sample is added to the set of agent goal locations. Then, as part of the iteration, the greedy sampler removes agent locations that are closer than a first threshold distance to the sample acquired. The greedy sampler then reduces the agent location probability of remaining agent locations that is closer than a second threshold distance. The process is repeated until the N samples are obtained.

In Block 706, trajectory completion of the agent is performed to each agent goal location to obtain a set of agent trajectories of the agent. In one or more embodiments, trajectory completion is performed independently for each agent goal location to determine the trajectory of the agent from the agents current position to the agent goal location. Trajectory completion may be performed using an MLP.

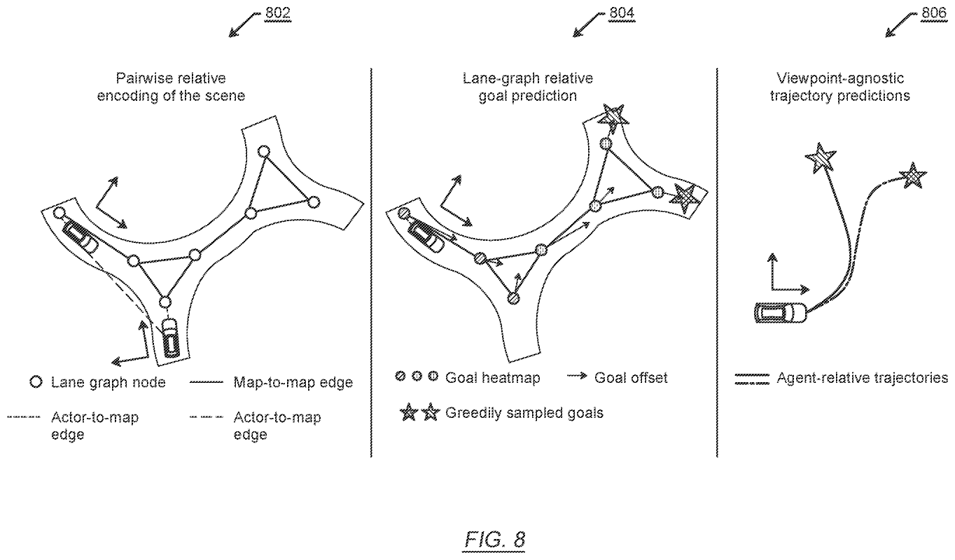

FIGS. 8-11 show an example in accordance with one or more embodiments. The following example is for explanatory purposes only and not intended to limit the scope of the invention.

FIG. 8 shows an example overall diagram of motion forecasting in accordance with one or more embodiments. One or more embodiments encodes the scene by reasoning about pairwise relative geometric relationships between the agents and the lane graph as shown in the left pane (802). As shown in the left pane (802), agents are cars and the dots are map element nodes (i.e., lane graph nodes in the example). The graph is formed by the map element edges connecting the map element nodes, the agent edges connecting the agent nodes (i.e., shown as cars in the example), and the map agent edges connecting each agent node to the closest map element node.

Moving to the middle pane (804), one or more embodiments predict a goal distribution using the lane graph nodes as anchors. In the example, the agent goal locations are for a single car and are denoted as stars that are located at an offset from a map element node. The closest map element node serves as the anchor for the agent goal location.

Moving to the right pane (806), a trajectory is generated conditioned on the agent goal location. In one or more embodiments, the trajectory is independent of the map element nodes. The architecture is viewpoint-invariant, thus allowing for shared computation across agents. For example, the second agent shown in the left pane may use the same heterogeneous graph to obtain a different set of agent goal locations and a different trajectory.

Graph neural networks (GNN) process graph structures by exchanging messages between node pairs connected by edges. One or more embodiments use a GNN architecture that will be extensively used in the next section as the backbone for encoding graphs composed of both agents and map nodes, and decoding future predictions from them. The goal of the architecture is to capture complex interactions between nodes in a heterogeneous spatial graph. By spatial, one or more embodiments mean that nodes have both a feature vector with general attributes as well as a pose describing its centroid and yaw. Heterogeneous here may mean that nodes may belong to different semantic categories, and their node attributes may have different dimensionality. This graph neural network models directional relationships via continuous edge attributes and discrete edge classes.

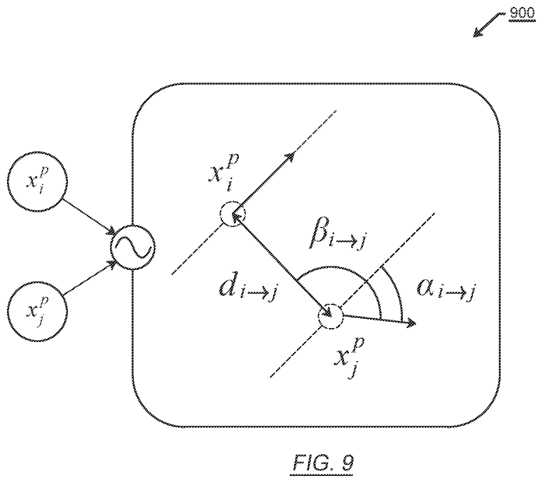

FIG. 9 shows an example diagram of the pairwise element position encoding (900) in accordance with one or more embodiments. In the example, xᵢ^{p}, and xⱼ^{p} are each an agent node or a map element node. Each node in the heterogeneous graph has a pose xᵢ^{p}, which is composed of a centroid cᵢ and a unit vector in the heading direction hᵢ. To represent the directional, pairwise relationship between node i and j (i.e., i→j), the displacement vector between each node's centroids v_{i→j}=cᵢ−cⱼ as well as the sine and cosine of the heading difference may be computed in the following set of equations (1).

sin(α_{i→j})=hᵢ×hⱼ,cos(α_{i→j})=hᵢ·hⱼ (1)

The displacement vector v_{i→j} depends on the arbitrary global frame the centroids are expressed in, and thus is not viewpoint invariant. To achieve invariance, one or more embodiments may utilize the centroid distance d_{i→j}=∥v_{i→j}∥², together with the sine and cosine of the angle between the displacement vector v_{i→j} and the heading hⱼ.

To make the centroid distances bounded, one or more embodiments may map each distance to a vector p_{i→j}=[p₁, . . . , p_{N}, r₁, . . . , r_{N}] composed of sine and cosine functions of N different frequencies that represent the range of distances that embodiments may be interested in (e.g., a few meters to hundreds of meters). More concretely, the vector may be represented using the following equations (2).

$${p}_{n} = sin ( {d}_{i \to j} exp ( \frac{4 n}{N} ) ) , {r}_{n} = cos ( {d}_{i \to j} exp ( \frac{4 n}{N} ) ) \qquad ( 2 )$$

The pair-wise geometric relationship of entities i and j can be summarized as a concatenation (⊕) using equation (3).

g_{i→j}^{a}=[sin(α_{i→j}),cos(α_{i→j}),sin(β_{i→j}),cos(β_{i→j})]⊕p_{i→j} (3)

The final positional encoding may be learned using equation (4).

e_{i→j}^{a}=MLP(g_{i→j}^{a}) (4)

Returning to FIG. 9, d_{i→j} is the distance between node i and node j, α_{i→j} is the angular difference between angles of heading of the node i compared to node j, β_{i→j} is the angular difference between an angle of heading of the second agent relative to a straight line measured by distance vector d_{i→j} between the node i and node j.

After calculating the values for d_{i→j}, α_{i→j}, and β_{i→j}, the vector g_{i→j}^{a} may be generated using equations (2) and (3). Then, the vector may be encoded using the MLP model to generate the edge value e_{i→j}^{a} that is used for the edge between node i and node j. The process may be repeated for each edge between nodes (e.g., agent node or map element node) in the graph structure (e.g., heterogeneous graph, agent layer, map element layer). The result is a set of initial values for the edges of the graph structure.

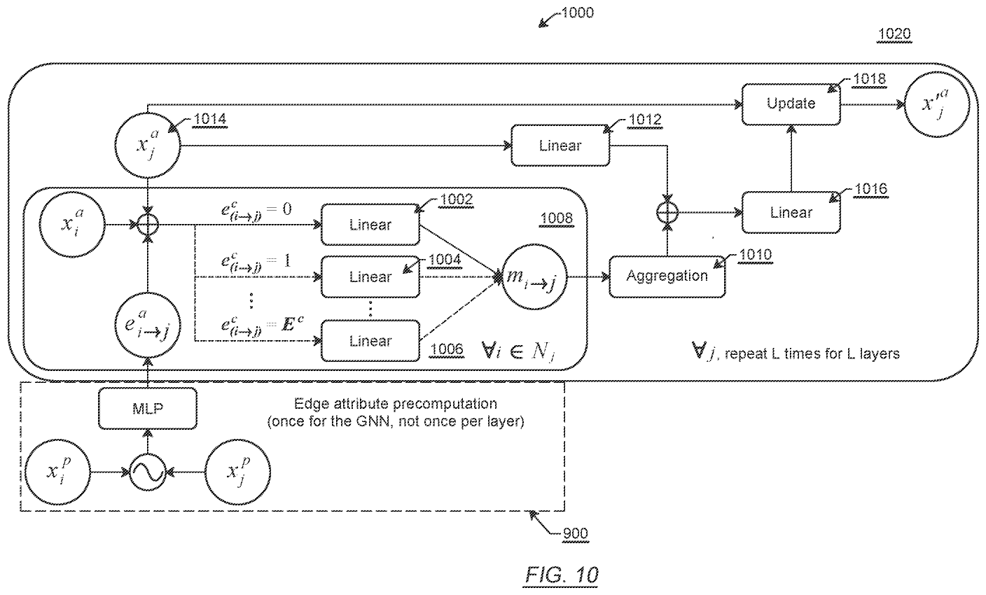

FIG. 10 shows a diagram of the heterogeneous message passing (HMP) layer (1000) of the GNN. Box (900) is the condensed version of FIG. 9. The goal of the HMP layer is to update the node features xⱼ^{a} in a directed graph by taking into account all its incoming neighbor nodes' features xⱼ^{a}∈Nⱼ as well as their pair-wise relative positional encodings e_{i→j}.

For each neighbor i∈Nⱼ, one or more embodiments compute a message m_{i→j} by linearly projecting the concatenation of the source features xⱼ^{a} and edge attributes e_{i→j}^{a}. The weights of the linear layer are different depending on the discrete edge class e_{i→j}^{c}, which may also be referred to as the type of edge. Namely, as shown in FIG. 10 by the different linear layers (1002, 1004, 1006), different linear layers are used for edge class e_{i→j}^{c}=0, edge class e_{i→j}^{c}=1, . . . , edge class e_{i→j}^{c}=E^{c}. The edge class may be, for example, agent edges that connect agent nodes, map element edges that connect map element nodes, and the agent map edges that connect agent nodes to map element nodes. The dimensionality of weights of the different linear layers (1002, 1004, 1006) depend on the dimensionality of the node features, which vary by node class. Then, incoming messages are aggregated using a permutation invariant aggregation function (e.g., max-pooling function (1008)). Subsequently, aggregated messages (1010) are concatenated with a linear projection (1012) of the node features (1014), and fused with another linear layer (1016). Finally, an update function (1018) (e.g., GRU cell) enables the HMP layer to keep or forget information from the previous features xⱼ^{a} into the updated features x′ⱼ^{a} (1020). The pair-wise relative heterogeneous GNN may be composed of a stack of multiple HMP layers.

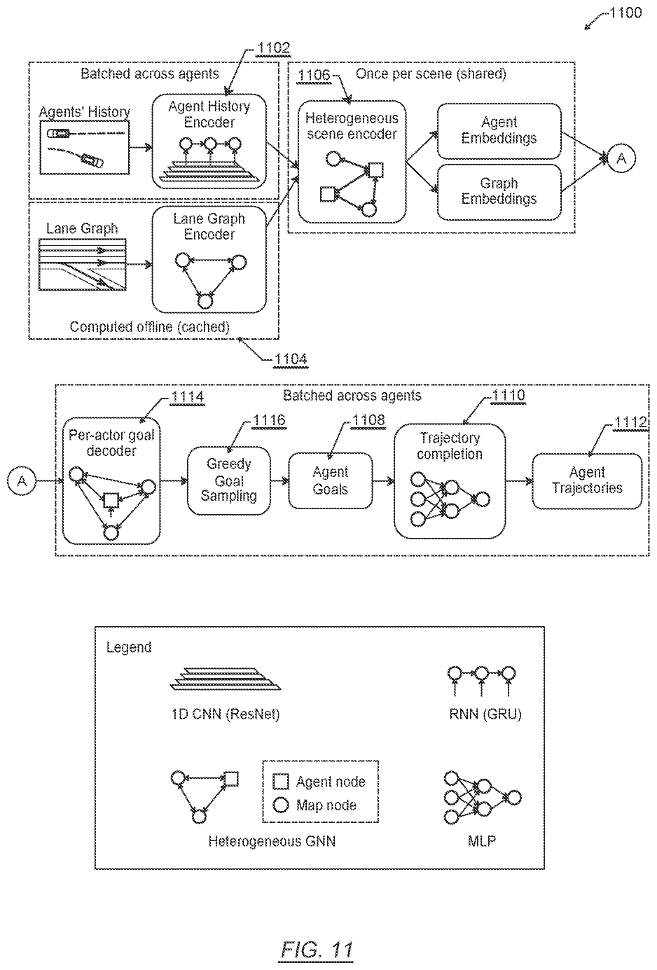

FIG. 11 shows an architecture (1100) of the overall system in accordance with one or more embodiments. Specifically, FIG. 11 is a more detailed and example diagram of the components shown in FIG. 4 in accordance with one or more embodiments. Forecast multi-agent future trajectories may be performed according to one or more embodiments based at least in part on the map as well as past trajectories. Towards this goal, agent features and map features may be computed separately (1102, 1104) because (i) the nature of the features is different (spatial-temporal vs. spatial), and (ii) efficiency—the map features can be computed offline as the map features only rely on the high-definition maps.

One or more embodiments may then leverage the HMP layers (1106 and as shown in FIG. 10) to model inter-class and intra-class interactions on a single heterogeneous graph that connects agents and map elements. Further, the future trajectory of each agent is predicted by first predicting the agent goal location (1108) (e.g., a waypoint at the end of the prediction time horizon), and subsequently predicting their full trajectory (1112) given the goal. An example operation is described below.

The agent history encoder (1102) is a viewpoint invariant representation to express the past trajectory as a sequence of pair-wise relative positional encodings between the past waypoints and the current pose. For example, the past trajectory may be encoded as More precisely, the past trajectory is encoded as τ=[e−_{T→0,} . . . , e−_{1→0}]ϵ [symbol] ^{T×D}, where e_{T→0} refers to the pair-wise relative positional encoding of the pose xₜ^{P} at a past time step t<0 with respect to the current pose x₀^{P} (as described in Eq. (4)).

The current time is t=0, and negative times denote the past with t=−T being the history horizon, and D is the dimensionality of the pair-wise relative positional encoding. One or more embodiments then pass each agent's features into a one dimensional CNN with residual connections followed by a GRU, and use the final hidden state of the GRU as the embedding of the agent's trajectory (1112). Intuitively, the one dimensional CNN can extract local temporal patterns and the GRU can aggregate them in a learnable hidden state. Further, the computation for all agents can be batched and thus inference is very efficient even in complex crowded scenes.

In the example, the agents are vehicles and the map elements are the lanes in which a vehicle may drive. Thus, the map element layer is a lane graph, and the map element nodes are lane nodes for the purposes of the example. A lane graph may be built by sampling the centerlines in the high-definition map at regular intervals (e.g., 3 m for urban, 10 m for highway) to obtain lane segments. Each lane segment is represented as a node in the graph that includes features such as its length, width, curvature, speed limit, and lane boundary type (e.g., solid, dashed). The lane nodes may be connected with four different relationships: successors, predecessors, left and right neighbors. For successors and predecessors, dilations (i.e., skip connections) may be included for {2; 3; 4; 5} hops in order to make the receptive field of the GNN grow faster over layers, which helps particularly with fast moving vehicles. Further, map element nodes may be sampled uniformly from crosswalk polygons since the map element nodes for crosswalks are highly relevant for pedestrians and vehicles interacting with pedestrians. To understand the interactions occurring at overlapping map entities (e.g., lanes at intersections, crosswalks and lanes), a “conflict” edge may be added for each pair of nodes in the graph that are less than 2.5 meters apart and belong to distinct map entities. One or more embodiments use a stack of the previously introduced HMP layers to update the embeddings of map element nodes in the graph.

The viewpoint agnostic lane graph encoder allows us to compute map embeddings offline for large-scale maps after training. Through memory-efficiency and coordinate frame invariance, the map embeddings may be computed for a large tile offline in a single inference pass over the lane graph encoder (1104), eliminating the need for stitching regions of map embeddings together. On the onboard side, a map provider may serve large map tiles to autonomy every several seconds which contain the cached lane graph embeddings, improving the virtual driver's reaction time.

Continuing with the example with the heterogeneous scene encoder, the agent and lane graph features are fused together using another stack of HMP layers (e.g., as shown in FIG. 10). The heterogeneous scene graph contains agent nodes and map element nodes, whose input attributes are initialized with the results of the previously described agent history encoder (1102) and lane graph encoder (1104), respectively.

In the example, the agent-to-map and map-to-agent edges may be created between agents and the lane graph node that is nearest to the agents' position at time t=0. For agent-to-agent, pairs of agent nodes of agents closer than a hundred meters are connected. At every round of message passing, the example system computes messages for the different edges of different edge types, and updates both the agent nodes and lane graph node embeddings with heterogeneous messages incoming from the different edge types.

Continuing with the goal-based decoding (1114), the goal prediction is modeled as a multi-class classification problem over lane graph nodes. The classification allows embodiments to leverage the rich map embeddings computed by the heterogeneous scene encoder. To achieve a resolution beyond that of the lane-graph, one or more embodiments may also regress a continuous offset for each candidate goal with respect to its lane-graph node anchor. To predict these classification scores and regression offsets, embodiments may create a graph composed of A connected components, one for each agent in the scene. Each connected component includes an actor and a copy of the map nodes. Namely, each agent node may have an individual graph that includes just the agent node and the map element nodes of the heterogeneous graph. Regarding the graph connectivity, the same map-to-map edges as in upstream components is preserved, and all possible map element node to actor node and actor node to map element node are added. The agent node and map element node features are initialized to the outputs of the heterogeneous scene encoder, and are updated by a stack of HMP layers.

Using the updated graph for the agent, greedy goal sampling (1116) may be performed. Predicting multi-modal trajectories may be used for the motion planner to be safe with respect to any future that might unfold. To predict K modes, at every iteration, one or more embodiments may (1) sample the goal with the highest probability, (2) remove every node closer than a threshold number of meters, (3) down weight every node closer than a threshold number of meters by a predefined factor or amount. One or more embodiments may repeat the process for K iterations. Thus, if the probability distribution is uni-modal, as many samples as possible should be drawn from it, while if the distribution is multi-modal (e.g., agent at intersection), it is desirable to sample from different modes even if the probability mass around each mode is imbalanced.

One or more embodiments may perform trajectory completion (1110) to the agent goal locations in parallel. One or more embodiments may perform the trajectory prediction in agent-relative coordinates such that the network can leverage the prior that vehicles initially progress along their heading direction (i.e., the x-axis). A shared MLP may be used across agent classes (e.g., vehicles, pedestrians and cyclists) that predicts the sequence of two dimensional waypoints as a flat vector in [symbol] ^{2Tf}, where Tf is the prediction time horizon. The sharing of the MLP layers across agent classes may be beneficial as some priors may exist that all trajectories follow.

To train the system, one or more embodiments may optimize a multi-task loss, which is a linear combination of three terms: goal classification, goal regression and trajectory completion. One or more embodiments may employ focal loss for goal classification, serving as a form of hard example mining One or more embodiments may supervise the offset regression only for the node that is closest to the goal, and may use a Huber loss in node frame. One or more embodiments may train the trajectory completion unit using teacher forcing, meaning that during training one or more embodiments may feed the ground-truth goal to the trajectory completion unit. One or more embodiments may further employ a Huber loss on each waypoint coordinate in agent-centric frame.

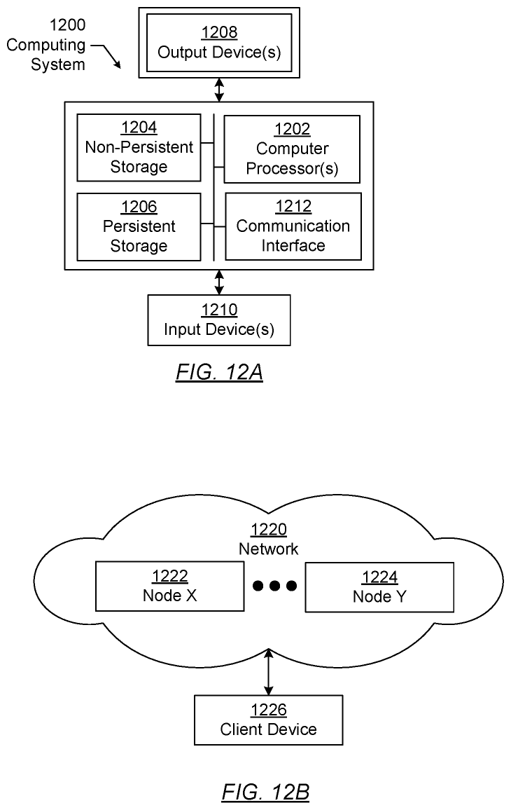

Embodiments may be implemented on a computing system specifically designed to achieve an improved technological result. When implemented in a computing system, the features and elements of the disclosure provide a significant technological advancement over computing systems that do not implement the features and elements of the disclosure. Any combination of mobile, desktop, server, router, switch, embedded device, or other types of hardware may be improved by including the features and elements described in the disclosure. For example, as shown in FIG. 12A, the computing system (1200) may include one or more computer processors (1202), non-persistent storage (1204), persistent storage (1206), a communication interface (1208) (e.g., Bluetooth interface, infrared interface, network interface, optical interface, etc.), and numerous other elements and functionalities that implement the features and elements of the disclosure. The computer processor(s) (1202) may be an integrated circuit for processing instructions. The computer processor(s) may be one or more cores or micro-cores of a processor. The computer processor(s) (1202) includes one or more processors. The one or more processors may include a central processing unit (CPU), a graphics processing unit (GPU), a tensor processing units (TPU), combinations thereof, etc.

The input devices (1210) may include a touchscreen, keyboard, mouse, microphone, touchpad, electronic pen, or any other type of input device. The input devices (1210) may receive inputs from a user that are responsive to data and messages presented by the output devices (1212). The inputs may include text input, audio input, video input, etc., which may be processed and transmitted by the computing system (1200) in accordance with the disclosure. The communication interface (1208) may include an integrated circuit for connecting the computing system (1200) to a network (not shown) (e.g., a local area network (LAN), a wide area network (WAN) such as the Internet, mobile network, or any other type of network) and/or to another device, such as another computing device.

Further, the output devices (1212) may include a display device, a printer, external storage, or any other output device. One or more of the output devices may be the same or different from the input device(s). The input and output device(s) may be locally or remotely connected to the computer processor(s) (1202). Many different types of computing systems exist, and the aforementioned input and output device(s) may take other forms. The output devices (1212) may display data and messages that are transmitted and received by the computing system (1200). The data and messages may include text, audio, video, etc., and include the data and messages described above in the other figures of the disclosure.

Software instructions in the form of computer readable program code to perform embodiments may be stored, in whole or in part, temporarily or permanently, on a non-transitory computer readable medium such as a storage device, a diskette, a tape, flash memory, physical memory, or any other computer readable storage medium. Specifically, the software instructions may correspond to computer readable program code that, when executed by a processor(s), is configured to perform one or more embodiments, which may include transmitting, receiving, presenting, and displaying data and messages described in the other figures of the disclosure.

The computing system (1200) in FIG. 12A may be connected to or be a part of a network. For example, as shown in FIG. 12B, the network (1220) may include multiple nodes (e.g., node X (1222), node Y (1224)). Each node may correspond to a computing system, such as the computing system shown in FIG. 12A, or a group of nodes combined may correspond to the computing system shown in FIG. 12A. By way of an example, embodiments may be implemented on a node of a distributed system that is connected to other nodes. By way of another example, embodiments may be implemented on a distributed computing system having multiple nodes, where each portion may be located on a different node within the distributed computing system. Further, one or more elements of the aforementioned computing system (1200) may be located at a remote location and connected to the other elements over a network.

The nodes (e.g., node X (1222), node Y (1224)) in the network (1220) may be configured to provide services for a client device (1226), including receiving requests and transmitting responses to the client device (1226). For example, the nodes may be part of a cloud computing system. The client device (1226) may be a computing system, such as the computing system shown in FIG. 12A. Further, the client device (1226) may include and/or perform all or a portion of one or more embodiments.

The computing system of FIG. 12A may include functionality to present raw and/or processed data, such as results of comparisons and other processing. For example, presenting data may be accomplished through various presenting methods. Specifically, data may be presented by being displayed in a user interface, transmitted to a different computing system, and stored. The user interface may include a graphical user interface (GUI) that displays information on a display device. The GUI may include various GUI widgets that organize what data is shown as well as how data is presented to a user. Furthermore, the GUI may present data directly to the user, e.g., data presented as actual data values through text, or rendered by the computing device into a visual representation of the data, such as through visualizing a data model.

As used herein, the term “connected to” contemplates multiple meanings. A connection may be direct or indirect (e.g., through another component or network). A connection may be wired or wireless. A connection may be temporary, permanent, or semi-permanent communication channel between two entities.

The various descriptions of the figures may be combined and may include or be included within the features described in the other figures of the application. The various elements, systems, components, and steps shown in the figures may be omitted, repeated, combined, and/or altered as shown from the figures. Accordingly, the scope of the present disclosure should not be considered limited to the specific arrangements shown in the figures.

In the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as by the use of the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

Further, unless expressly stated otherwise, or is an “inclusive or” and, as such includes “and.” Further, items joined by an or may include any combination of the items with any number of each item unless expressly stated otherwise.

In the above description, numerous specific details are set forth in order to provide a more thorough understanding of the disclosure. However, it will be apparent to one of ordinary skill in the art that the technology may be practiced without these specific details. In other instances, well-known features have not been described in detail to avoid unnecessarily complicating the description. Further, other embodiments not explicitly described above can be devised which do not depart from the scope of the claims as disclosed herein. Accordingly, the scope should be limited only by the attached claims.

What is claimed is:

1. A method comprising:
obtaining map data of a geographic region and a plurality of historical trajectories of a plurality of agents located in the geographic region, the map data comprising a plurality of map elements, wherein the plurality of agents and the plurality of map elements have a corresponding plurality of physical locations in the geographic region;
building, from the plurality of historical trajectories and the map data, a heterogeneous graph for the plurality of agents and the plurality of map elements, wherein the heterogeneous graph defines the corresponding plurality of physical locations of the plurality of agents and the plurality of map elements relative to each other of the plurality of agents and the plurality of map elements;
modelling, by a first graph neural network, a plurality of agent actions of an agent of the plurality of agents using the heterogeneous graph to generate an agent goal location; and
operating an autonomous system based on the agent goal location.

2. The method of claim 1, wherein operating the autonomous system comprises:
outputting by an autonomous system controller of a virtual driver of the autonomous system, a control signal to an actuator of the autonomous system.

3. The method of claim 2, wherein the control signal is intercepted by a simulator that simulates the autonomous system in a simulated environment to train the virtual driver.

4. The method of claim 1, wherein operating the autonomous system comprises:
generating, by a simulator, a simulated environment simulating the agent being a virtual agent moving in the geographic region according to the agent goal location,
outputting, by a virtual driver, a control signal based at least in part on simulated sensor input generated by the moving of the virtual agent in the geographic region, and
simulating, by the simulator, the autonomous system moving in the simulated environment responsive to the control signal,
wherein the plurality of agents and the autonomous system are virtually located in the geographic region as simulated by the simulator.

5. The method of claim 1, wherein building the heterogeneous graph comprises:
calculating, from the plurality of historical trajectories, a first plurality of relative positions of the agent with respect a subset of the plurality of agents, the subset excluding the agent,
calculating, from a historical trajectory of the agent, a second plurality of relative positions of the agent with respect to a current position of the agent, wherein the historical trajectory is in the plurality of historical trajectories, and
generating an agent position encoding for the agent that encodes the first plurality of relative positions and the second plurality of relative positions.

6. The method of claim 5, wherein building the heterogeneous graph further comprises:
generating an agent layer of the heterogeneous graph using a plurality of agent position encodings generated for the plurality of agents, wherein the plurality of agent position encodings comprises the agent position encoding,
wherein the agent layer comprises a plurality of agent nodes for the plurality of agents, the plurality of agent nodes connected by a plurality of edges based on distances between the plurality of agents, the plurality of edges having a corresponding agent position encoding of the plurality of agent position encodings for the corresponding pair of agent nodes of the plurality of agent nodes.

7. The method of claim 1, wherein building the heterogeneous graph further comprises:
obtaining the plurality of physical locations of the plurality of map elements,
calculating, from the plurality of physical locations of the plurality of map elements, a plurality of relative positions of the plurality of map elements with respect to other of the plurality of map elements,
generating a plurality of map element encodings of the plurality of relative positions, and
generating a map layer of the heterogeneous graph using the plurality of map element encodings.

8. The method of claim 1, wherein building the heterogeneous graph further comprises:
generating an agent layer of the heterogeneous graph using a plurality of agent position encodings generated for the plurality of agents,
wherein the agent layer comprises a plurality of agent nodes for the plurality of agents, the plurality of agent nodes connected by a first plurality of edges based on distances between the plurality of agent, the first plurality of edges comprising a corresponding agent position encoding of the plurality of agent position encodings for the corresponding agents, and
wherein the plurality of agent position encodings encode relative positions of the plurality of agents with respect to each other,
generating a map layer of the heterogeneous graph using a plurality of map element encodings generated for the plurality of map elements,
wherein the map layer comprises a plurality of map element nodes for the plurality of map elements, the plurality of map element nodes connected by a second plurality of edges based on distances between the plurality of map elements, the second plurality of edges comprising a corresponding map element encoding of the plurality of map element encodings for the corresponding map elements, and
wherein the plurality of map element encodings encode relative positions of the plurality of map elements with respect to each other, and
connecting the agent layer to the map layer using a third plurality of edges based on relative positions of the plurality of agents to the plurality of map elements to generate the heterogenous graph.

9. The method of claim 8, further comprising:
executing a scene encoder on the heterogeneous graph to generate a plurality of agent embeddings of the plurality of agents and a plurality of graph embeddings of the plurality of map elements.

10. The method of claim 9, wherein the scene encoder comprise a second graph neural network.

11. The method of claim 10, wherein the second graph neural network comprises a first linear layer specific to the first plurality of edges, a second linear layer specific to the second plurality of edges, and a third linear layer specific to the third plurality of edges.

12. The method of claim 1, wherein modeling the plurality of agent actions comprises:
generating, by executing the first graph neural network for the agent, an agent location probability for each of a plurality of locations, the agent location probability indicating a probability that the agent is moving to be located at a location defined by a map element and an offset from the map element, and
wherein the map element is in the plurality of map elements and the location is in the plurality of locations, and
sampling the plurality of locations using the agent location probability to obtain a plurality of agent goal locations, wherein the agent goal location is in the plurality of agent goal locations.

13. The method of claim 12, wherein sampling comprises:
repetitively performing:
sampling, according to the agent location probability of the plurality of locations, the plurality of locations,
removing, from the plurality of locations, a first location having a distance to a current location of the agent less than a first threshold, and
reducing the agent location probability of a second location having a distance to the current location of the agent less than a second threshold,
wherein the first location and the second location are in the plurality of locations.

14. The method of claim 1, further comprising:
generate a trajectory of the agent to the agent goal location, wherein operating the autonomous system is further based on the trajectory.

15. The method of claim 13, wherein a multilayer perceptron model is used to perform trajectory completion of the trajectory of the agent.

16. The method of claim 1, wherein, in the heterogenous graph, a relative position of a first agent to a second agent is defined by:
a distance between the first agent to the second agent,
a first difference between angles of heading of the first agent compared to the second agent, and
a second difference between an angle of heading of the second agent relative to a straight line between the first agent and the second agent.

17. A system comprising:
a computer processor; and
non-transitory computer readable medium for causing the computer processor to perform operations comprising:
obtaining map data of a geographic region and a plurality of historical trajectories of a plurality of agents located in the geographic region, the map data comprising a plurality of map elements, wherein the plurality of agents and the plurality of map elements have a corresponding plurality of physical locations in the geographic region,
building, from the plurality of historical trajectories and the map data, a heterogeneous graph for the plurality of agents and the plurality of map elements, wherein the heterogeneous graph defines the corresponding plurality of physical locations of the plurality of agents and the plurality of map elements relative to each other of the plurality of agents and the plurality of map elements,
modelling, by a first graph neural network, a plurality of agent actions of an agent of the plurality of agents using the heterogeneous graph to generate an agent goal location, and
operating an autonomous system based on the agent goal location.

18. The system of claim 17, wherein the system comprises:
a pairwise agent encoder comprising a convolutional neural network and a recurrent neural network to generate a plurality of agent encodings of the plurality of agents,
a pairwise map element encoder to generate a plurality of map element encodings of the plurality of map elements,
a scene encoder comprising a second graph neural network that uses the plurality of agent encodings and the plurality of map element encodings to generate the heterogenous graph,
the first graph neural network to generate a plurality of agent location probabilities,
a greedy sampler to sample the plurality of agent location probabilities to obtain the agent goal location, and
a multilayer perceptron model to generate a trajectory to the agent goal location.

19. A non-transitory computer readable medium comprising computer readable program code for causing a computer system to perform operations comprising:
obtaining map data of a geographic region and a plurality of historical trajectories of a plurality of agents located in the geographic region, the map data comprising a plurality of map elements, wherein the plurality of agents and the plurality of map elements have a corresponding plurality of physical locations in the geographic region;
building, from the plurality of historical trajectories and the map data, a heterogeneous graph for the plurality of agents and the plurality of map elements, wherein the heterogeneous graph defines the corresponding plurality of physical locations of the plurality of agents and the plurality of map elements relative to each other of the plurality of agents and the plurality of map elements;
modelling, by a first graph neural network, a plurality of agent actions of an agent of the plurality of agents using the heterogeneous graph to generate an agent goal location; and
operating an autonomous system based on the agent goal location.

20. The non-transitory computer readable medium of claim 19, wherein building the heterogeneous graph further comprises:
generating an agent layer of the heterogeneous graph using a plurality of agent position encodings generated for the plurality of agents,
wherein the agent layer comprises a plurality of agent nodes for the plurality of agents, the plurality of agent nodes connected by a first plurality of edges based on distances between the plurality of agent, the plurality of agent nodes comprising a corresponding agent position encoding of the plurality of agent position encodings for the corresponding agent, and
wherein the plurality of agent position encodings encode relative positions of the plurality of agents with respect to each other,
generating a map layer of the heterogeneous graph using a plurality of map element encodings generated for the plurality of map elements,
wherein the map layer comprises a plurality of map element nodes for the plurality of map elements, the plurality of map element nodes connected by a second plurality of edges based on distances between the plurality of map elements, the plurality of map element nodes comprising a corresponding map element encoding of the plurality of map element encodings for the corresponding map element, and
wherein the plurality of map element encodings encode relative positions of the plurality of map elements with respect to each other, and
connecting the agent layer to the map layer using a third plurality of edges based on relative positions of the plurality of agents to the plurality of map elements to generate the heterogenous graph.
